(19) United States
(12) Patent Application Publication
(10) Pub. No.: US 2020/0285826 A1
(43) Pub. Date: Sep. 10, 2020

(54) DISPLAY SUBSTRATE AND DISPLAY DEVICE

(71) Applicant: BOE TECHNOLOGY GROUP CO., LTD., Beijing (CN)

(72) Inventors: Pinchao GU, Beijing (CN); Xue DONG, Beijing (CN); Haisheng WANG, Beijing (CN); Yingming LIU, Beijing (CN); Rui XU, Beijing (CN); Changfeng LI, Beijing (CN); Yuzhen GUO, Beijing (CN); Yunke QIN, Beijing (CN)

(73) Assignee: BOE Technology Group Co., Ltd., Beijing (CN)

(21) Appl. No.: 15/774,436

(22) PCT Filed: Oct. 23, 2017
(86) PCT No.: PCT/CN2017/107351

§ 371 Date: May 8, 2018

(30) Foreign Application Priority Data
Mar. 28, 2017 (CN) 201710192831.7

(51) Int. Cl. G06K 9/00; H01L 27/32; G02B 5/30

(52) U.S. Cl. CPC G06K 9/0004; G02B 5/3058; H01L 27/3227; H01L 27/3232

(57) ABSTRACT

The present disclosure provides a display substrate and a display device. The display substrate of the present disclosure comprises: an array (1) of optical sensing devices; an optical structure (2) disposed above the array (1) of optical sensing devices, wherein the optical structure (2) comprises a plurality of optical units (20) each of which comprises a light shading region (Q1) and a light transmission region (Q2); and a pixel array (3) disposed above the optical structure (2), wherein the pixel array (3) comprises a plurality of pixel units (30) each of which comprises subpixels of different colors.

### CROSS-REFERENCE TO RELATED APPLICATIONS

This application is a U.S. National Stage under 35 U.S.C. § 371 of International Application No. PCT/CN2017/107351, as filed on Oct. 23, 2017, which claims the benefit of priority to the Chinese Patent Application No. 201710192831.7, filed on Mar. 28, 2017. The disclosure of each application is incorporated herein by reference in its entirety.

### TECHNICAL FIELD

The present disclosure relates to a display substrate and a display device.

### BACKGROUND

Fingerprint is an invariant feature that is innate, unique and can distinguish one people from others. It is composed of a series of ridges and valleys on the skin surface of the fingertip. The minutes of the ridges and valleys usually include bifurcations of the ridges, ridge ending, arches, tent-shaped arches, left spin, right spin, whorl or double spins, and etc., which decide the uniqueness of the fingerprint pattern. The thus developed fingerprint recognition technology is a technology used for personal identity authentication, and according to the difference between the acquisition and input methods of the fingerprint, the currently widely used and well-known technologies comprise: optical imaging, heat-sensitive sensors, human body infrared sensors, and etc.

### SUMMARY

Embodiments according to the present disclosure relate to a display substrate, comprising:

an array of optical sensing devices;

an optical structure disposed above the array of optical sensing devices, wherein the optical structure comprises a plurality of optical units each of which comprises a light shading region and a light transmission region; and

a pixel array disposed above the optical structure, wherein the pixel array comprises a plurality of pixel units each of which comprises subpixels of different colors.

Alternatively, a width of each of the optical units is “a” times a width of one of the subpixels in the pixel unit, where “a” is an integer greater than or equal to 1.

Alternatively, a width of each of the optical units is “im” times a width of one subpixel in the pixel unit, where “i” is a number of the subpixels in each pixel unit, and “m” is an integer greater than or equal to 1. In other words, the width of each of the optical units is m times the width of one of the pixel units.

Alternatively, the light transmission region in each of the optical units is arranged corresponding to “n” optical sensing devices in the array of optical sensing devices, where “n” is an integer greater than or equal to 1.

Alternatively, the light transmission regions in the plurality of optical units are arranged corresponding to one optical sensing device in the array of optical sensing devices.

Alternatively, the light shading region in each of the optical units is provided with, in turn, a first light shading layer, a first light transmission layer and a second light shading layer, in a direction away from the array of optical sensing devices.

Further alternatively, the light transmission region in each of the optical units is provided with a second light transmission layer, and each of the first light transmission layers is integrally formed with the second light transmission layer.

Further alternatively, a material of the first light shading layer and the second shading layer is a black matrix or metal; a material of the first light transmission layer is polyimide or glass.

Alternatively, the light shading region of each of the optical units is provided with a light shading body, and a through-hole defined by any adjacent two of the light shading bodies is the light transmission region.

Embodiments according to the present disclosure relate to a display device comprising the aforementioned display substrate.

Alternatively, the display device further comprises, in turn, a package layer, a polarizer, an optical adhesive and a protective glass arranged in a direction away from the pixel array.

### BRIEF DESCRIPTION OF THE DRAWINGS

FIG. 1 is a schematic diagram showing a structure of a display substrate in which one optical unit corresponds to one subpixel in the pixel unit according to some embodiments of the present disclosure;

FIG. 2 is a structural diagram of a display substrate in which one optical unit corresponds to one pixel unit according to some embodiments of the present disclosure;

FIG. 3 is a structural diagram of a display substrate in which one optical unit corresponds to a plurality of pixel units according to some embodiments of the present disclosure;

FIG. 4 is a schematic diagram of an optical structure in a display substrate according to some embodiments of the present disclosure;

FIG. 5 is a schematic diagram of an optical structure in a display substrate according to some embodiments of the present disclosure;

FIG. 6 is a schematic diagram showing a display substrate in which the light transmission region of one optical unit corresponds to one optical sensing device according to some embodiments of the present disclosure;

FIG. 7 is a schematic diagram showing a display substrate in which the light transmission region of one optical unit corresponds to a plurality of optical sensing devices according to some embodiments of the present disclosure;

FIG. 8 is a schematic diagram showing a display substrate in which the light transmission region of a plurality of optical units corresponds to one optical sensing device according to some embodiments of the present disclosure;

FIG. 9 is a schematic diagram showing a structure of a display device according to some other embodiments of the present disclosure.

### DETAILED DESCRIPTION

In order to enable those skilled in the art to better understand the technical solutions of the present disclosure, the present disclosure will be further described in detail in the following in combination with the accompanying drawings and the embodiments.

A touch control substrate with fingerprint recognition function in the related technologies generally comprises an array of optical sensing devices and a pixel array disposed above the array of optical sensing devices, and the pixel array comprises a plurality of pixel units each comprising a plurality of subpixels of different colors. The metal lines (these metals are driving lines used to drive the subpixels) beneath each subpixel have different areas, as a result, after the occurrence of a touch, a uniform light emitted by each subpixel is reflected from the finger onto the light path of the array of optical sensing devices. Although the subpixels in the pixel array are evenly distributed, the lights emitted by the different subpixels have different transmittances after they transmit from the side of their respective metal lines beneath. As a result, optical sensing devices in the array of optical sensing devices, which should have received the same proportion of light intensity reflected by the finger, now receive a reduced light of different proportions of intensity. In this way, the image acquisition capability of the optical sensing devices is worsened. When the light reflected by the finger is received, the valleys and ridges of the fingerprint will be blurred and cannot be discriminated from one another, and it is difficult to acquire the fingerprint image.

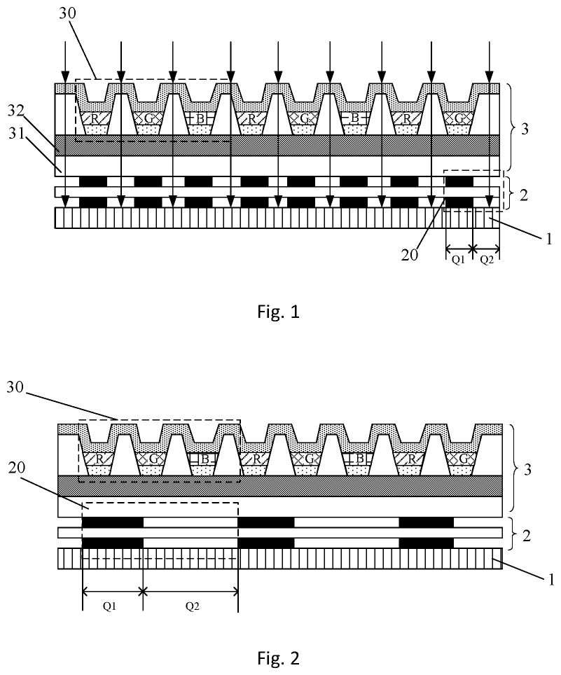

As shown in FIG. 1, some embodiments according to the present disclosure provide a display substrate, comprising: an array 1 of optical sensing devices; an optical structure 2 disposed above the array 1 of optical sensing devices; and a pixel array 3 disposed above the optical structure 2. The optical structure 2 comprises a plurality of optical units 20 each comprising a light shading region Q1 and a light transmission region Q2. The pixel array 3 comprises a plurality of pixel units 30 each comprising subpixels of different colors.

Since in the display substrate of this embodiment, each optical unit 20 comprises a light transmission region Q2 and a light shading region Q1, in other words, light can transmit through only the light transmission region Q2, when a touch occurs on the display substrate, an emission angle of the light reflected, after the light from the subpixels in the pixel unit 30 above the optical unit 20 irradiates the touch object (including the finger), can be limited, so that only the light within a certain angle can transmit through the optical unit 20 and reach the array 1 of optical sensing devices beneath. Therefore, the object touching the display substrate can obtain a clear and sharp image in the array of optical sensing devices, and a blur will not occur due to crosstalk of lights from different directions.

It should be noted here that, the pixel array 3 in this embodiment is an organic electroluminescent or organic light emitting diode (OLED) pixel array 3. The “width of optical unit 20” in this embodiment refers to a distance of the optical unit 20 in a row direction of the pixel array 3. The “width of pixel unit 30” refers to a distance of the pixel unit 30 in the row direction of the pixel array 3. The “width of subpixel” refers to a distance of the subpixel in the row direction of the pixel array 3. The pixel array 3 includes a substrate 31, a driving layer 32 (forming a pixel driving circuit) disposed above the substrate 31, and a pixel unit 30 disposed above the driving layer 32. The number of subpixels in each pixel unit 30 is i. An example is described in the following in which each pixel unit 30 comprises a red subpixel, a green subpixel, and a blue subpixel (i.e., i=3). Each subpixel comprises an OLED light-emitting device consisting of a cathode, an anode, and a light-emitting layer arranged between the cathode and the anode.

In one embodiment of this disclosure, the width of each optical unit 20 is “a” times the width of one subpixel of the pixel unit 30, where “a” is an integer greater than or equal to 1. As shown in FIG. 1, each optical unit 20 is arranged corresponding to one subpixel in the pixel unit 30. That is, the width of each optical unit 20 is 1 times the width of one subpixel in the pixel unit 30, i.e., a=1. In this embodiment of this application, each optical unit 20 can also be arranged corresponding to a number (a) of subpixels, that is, the width of each optical unit 20 can also be “a” times the width of one subpixel in the pixel unit 30.

In addition, each subpixel further comprises a pixel driving circuit generally located beneath the OLED light-emitting device, and a metal signal line connected to the pixel driving circuit, for providing a driving signal for the OLED light-emitting device. Although the metal signal lines located beneath the subpixels of different colors occupy different areas, that is, for each OLED light-emitting device, the light reflected from the side of the metal signal line beneath has a different transmittance, for each pixel unit 30, the total transmittance of the light reflected from the sides of the metal signal lines beneath the individual OLED light-emitting devices in the pixel unit 30 is the same.

Alternatively, a width of each of the optical units 20 is “im” times a width of one subpixel in the pixel unit 30, where “i” is a number of the subpixels in each pixel unit, and “m” is an integer greater than or equal to 1. In other words, the width of each optical unit 20 is “m” times the width of one pixel unit 30.

The display substrate in this embodiment is provided with an optical structure 2, and a width of each of the optical units in the optical structure 2 is “im” times a width of one subpixel in the pixel unit 30, where “i” is a number of the subpixels in each pixel unit, and “m” is an integer greater than or equal to 1. In other words, one optical unit 20 is arranged corresponding to m pixel units 30. Moreover, the total transmittance of the light reflected from the sides of the metal signal lines beneath the individual subpixels in each pixel unit 30 is the same, and similarly, the total transmittance of the light reflected from the sides of the metal signal lines beneath the individual subpixels in each plurality of pixel units 30 is also the same, so the same light transmits through every “m” pixel units 30. Thereafter, the light passing through the lower corresponding optical unit 20 is reduced in the same ratio, and the light then passes through the optical structure 2 and arrives at the lower array 1 of optical sensing devices to obtain an also uniformly reduced light intensity, so the optical sensing device 30 uniformly acquires the image of the object on the display substrate. In particular, if the object is a finger, it is possible to acquire the valleys and ridges in the fingerprint of the finger to achieve fingerprint recognition.

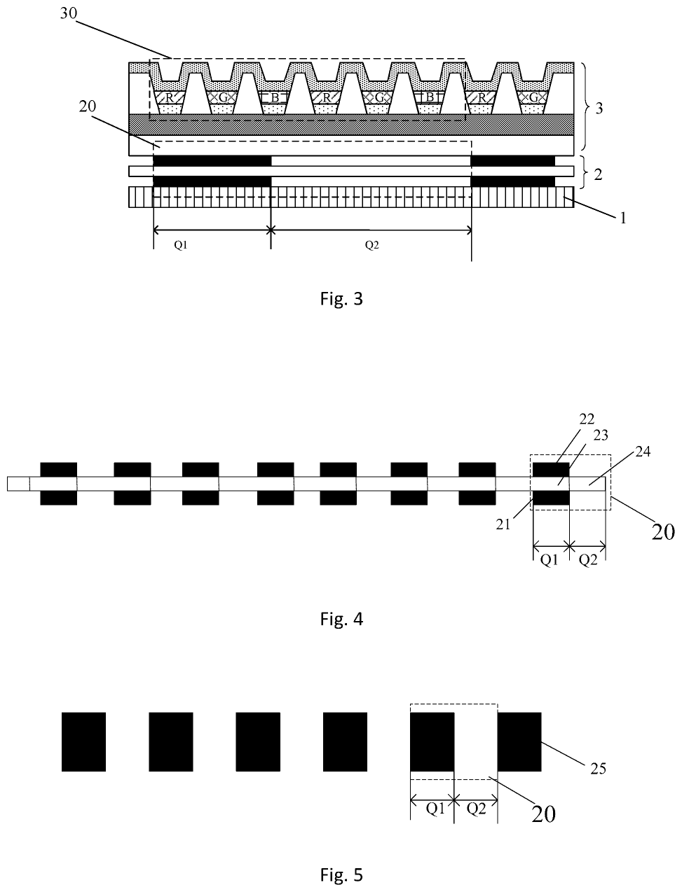

Among them, as shown in FIG. 2, one optical structure 2 in the optical structures 2 of the display substrate in this embodiment is arranged alternatively corresponding to one pixel unit 30, i.e., m=1 (at this time, a=i), and at this time, comparatively minute and fine images such as fingerprint can be recognized. As shown in FIG. 3, of course, it can also be that one optical unit 20 corresponds to a plurality of display units, i.e., m>1, and such a setting can be used to roughly recognize an object with larger lines such as palm print. At this time, the image obtained by the array of the optical sensing devices has rougher details, but the overall structure is recognizable. Since there is not too much information recognizable, the processing time of the terminal can be saved, such that the terminal is more rapid and saves more power, and this is very essential to the mobile terminal.

Specifically, as shown in FIG. 4, for each optical unit 20, the light shading region Q1 can comprise a first light shading layer 21, a first light transmission layer 23 and a second light shading layer 22 arranged in this order in a direction away from the array 1 of optical sensing devices. That is, the optical unit 20 is composed of two layers of light shading material with a layer of light transmission material sandwiched therebetween. The material of the first light shading layer 21 and the second light shading layer 22 is black matrix or metal. Of course, it may be other composite materials, as long as light cannot transmit through it. The material of the first light transmission layer 23 is polyimide or glass. Of course, the first light transmission layer 23 can be an air layer, and it also can be other composite materials, as long as light can transmit through it. Moreover, for the light transmission region Q2 in each optical unit 20, since the light transmission region Q2 allows light to transmit therethrough, no material can be provided in the light transmission region Q2. Of course the second light transmission layer 24 can be formed while forming the first light transmission layer, and at this time the individual first light transmission layer 23 is formed integrally with the second light transmission layer 24, and the two are made of the same material. This can simplify the fabrication process of the optical unit 20.

Of course, the light shading region Q1 of each optical unit 20 can also adopt the structure of the light shading body 25, and a through-hole defined by any adjacent two of the light shading bodies 25 is the light transmission region Q2, as shown in FIG. 5. Such a structure can be realized by depositing an entire layer of light shading material, and then etching at a position corresponding to the light transmission region Q2 of each optical unit 20 to form the through-hole.

It should be noted here that, a ratio of the light shading region Q1 and light transmission region Q2 in each optical unit 20 can be varied, that is, the light shading region Q1 is wider and the corresponding light transmission region Q2 is narrower, or the light shading region Q1 is narrower and the corresponding light transmission region Q2 is wider. The width of the light shading region Q1 in the optical unit 20 is relatively larger, so as to deal with a different OLED module thickness and a thickness of the opaque material in the optical unit 20, thereby limiting the angle of light from the pixel unit 30 above. Therefore, only the light of a certain angle can pass through the optical structure 2 to reach the array 1 of optical sensing devices.

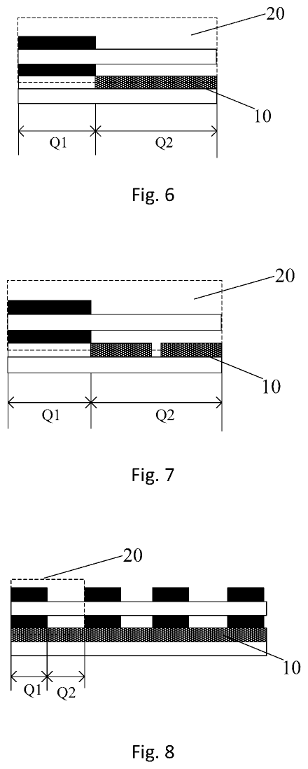

The light transmittance region Q2 in each optical unit 20 is arranged corresponding to the n optical sensing devices 10 in the array 1 of optical sensing devices, where n is an integer greater than or equal to 1. In other words, the light transmittance region Q2 in one optical unit 20 is arranged corresponding to one optical sensing device 10, as shown in FIG. 6. Otherwise, the light transmittance region Q2 in one optical unit 20 is arranged corresponding to a plurality of optical sensing device 10, as shown in FIG. 7. Of course, it can also be that, the light transmittance regions Q2 in a plurality of optical unit 20 is arranged corresponding to one optical sensing device 10 in the array 1 of optical sensing devices, as shown in FIG. 8.

The size of the optical sensing device 10 in each of the above implementations depends on the material of the optical sensing device 10 and the size of the display substrate. The array 1 of optical sensing devices can be composed of a thin film transistor and an optical sensing device 10, and the optical sensing device 10 can be a photoelectric device.

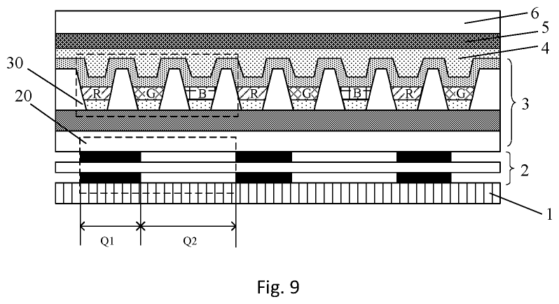

As shown in FIG. 9, some other embodiments according to the present disclosure provides a display device comprising the display substrate in the aforementioned embodiments. Of course, the display device further comprises a package layer 4, a polarizer, an optical adhesive 5 and a protective glass 6 arranged in this order in a direction away from the pixel array 3.

As the display device in this embodiment includes the display substrate in the above embodiments, and the optical structure 2 arranged in the display substrate of the above embodiments, wherein each optical unit 20 includes a light transmission region Q2 and a light shading region Q1, that is, only the light transmittance area Q2 can allow light to transmit threethrough. When a touch occurs on the display substrate, an emission angle of the light reflected, after the light from the subpixels in the pixel unit 30 above the optical unit 20 irradiates the touch object (including the finger), can be limited, so that only a certain angle of light can transmit through this optical unit 20 and reach the array 1 of optical sensing devices beneath, such that the object touching the display substrate can obtain a clear and sharp image in the array of optical sensing devices, and a blur due to crosstalk of lights from different directions will not occur. In one embodiment of the present disclosure, a width of each optical unit 20 is “a” times a width of one subpixel in the pixel unit 30, where “a” is an integer greater than or equal to 1. In this embodiment, a width of each optical unit 20 in the optical structure 2 may be “im” times a width of one of the subpixels in the pixel unit 30, where “I” is a number of the subpixels in each pixel unit, and “m” is an integer greater than or equal to 1. In other words, one optical unit 20 may be arranged corresponding to m pixel units 30. Moreover, the total transmittance of the light reflected from the sides of the metal signal lines beneath the individual subpixels in each pixel unit 30 is the same, and similarly, the total transmittance of the light reflected from the sides of the metal signal lines beneath the individual subpixels in each plurality of pixel units 30 is also the same, so the same light transmits through each m pixel units 30. Thereafter, the light passing through the lower corresponding optical unit 20 is reduced in the same ratio, and the light then passes through the optical structure 2 and arrives at the lower array 1 of optical sensing devices to obtain an also uniformly reduced light intensity, so the optical sensing device 30 uniformly acquires the image of the object on the display substrate. In particular, if the object is a finger, it is possible to acquire the valleys and ridges in the fingerprint of the finger to achieve fingerprint recognition.

The display device can be an electroluminescent display device such as electronic paper, OLED panel, mobile phone, tablet, television set, monitor, notebook computer, digital photo frame, navigator, and any product or component with the display functionality.

It should be appreciated that, the above embodiments merely are illustrative embodiments adopted for explaining the principle of the present disclosure, but the present disclosure is not limited thereto. Those skilled in the art could make various variations and modifications within the spirit and substance of the present disclosure, and all these variations and modifications are also regarded as the scope of protection of the present disclosure.

1. A display substrate, comprising:
an array of optical sensing devices;
an optical structure disposed above the array of optical sensing devices, wherein the optical structure comprises a plurality of optical units each of which comprises a light shading region and a light transmission region; and
a pixel array disposed above the optical structure, wherein the pixel array comprises a plurality of pixel units each of which comprises subpixels of different colors.

2. The display substrate according to claim 1, wherein a width of each of the plurality of optical units is “a” times a width of one of the subpixels in the plurality of pixel units, where “a” is an integer greater than or equal to 1.

3. The display substrate according to claim 1, wherein a width of each of the plurality of optical units is “im” times a width of one of the subpixels in the plurality of pixel units, where “i” is a number of the subpixels in each of the plurality of pixel units, and “m” is an integer greater than or equal to 1.

4. The display substrate according to claim 1, wherein the light transmission region in each of the plurality of optical units is arranged corresponding to “n” optical sensing devices in the array of optical sensing devices, where “n” is an integer greater than or equal to 1.

5. The display substrate according to claim 1, wherein the light transmission regions in the plurality of optical units are arranged corresponding to one optical sensing device in the array of optical sensing devices.

6. The display substrate according to claim 1, wherein the light shading region in each of the plurality of optical units is provided with, in turn, a first light shading layer, a first light transmission layer and a second light shading layer, in a direction away from the array of optical sensing devices.

7. The display substrate according to claim 6, wherein the light transmission region in each of the plurality of optical units is provided with a second light transmission layer, and each of the first light transmission layers is integrally formed with the second light transmission layer.

8. The display substrate according to claim 6, wherein a material of the first light shading layer and the second light shading layer is a black matrix or metal;
a material of the first light transmission layer is polyimide or glass.

9. The display substrate according to claim 1, wherein the light shading region of each of the plurality of optical units is provided with a light shading body, and a through-hole defined by any adjacent two of the light shading bodies is the light transmission region.

10. A display device comprising a display substrate, the display substrate comprising:
an array of optical sensing devices;
an optical structure disposed above the array of optical sensing devices, wherein the optical structure comprises a plurality of optical units each of which comprises a light shading region and a light transmission region; and
a pixel array disposed above the optical structure, wherein the pixel array comprises a plurality of pixel units each of which comprises subpixels of different colors.

11. The display device according to claim 10, further comprising, in turn, a package layer, a polarizer, an optical adhesive and a protective glass arranged in a direction away from the pixel array.

12. The display device according to claim 10, wherein a width of each of the plurality of optical units is “a” times a width of one of the subpixels in the plurality of pixel units, where “a” is an integer greater than or equal to 1.

13. The display device according to claim 12, wherein a width of each of the plurality of optical units is “im” times a width of one of the subpixels in the plurality of pixel units, where “i” is a number of the subpixels in each of the plurality of pixel units, and “m” is an integer greater than or equal to 1.

14. The display device according to claim 10, wherein the light transmission region in each of the plurality of optical units is arranged corresponding to “n” optical sensing devices in the array of optical sensing devices, where “n” is an integer greater than or equal to 1.

15. The display device according to claim 10, wherein the light transmission regions in the plurality of optical units are arranged corresponding to one optical sensing device in the array of optical sensing devices.

16. The display device according to claim 10, wherein the light shading region in each of the plurality of optical units is provided with, in turn, a first light shading layer, a first light transmission layer and a second light shading layer, in a direction away from the array of optical sensing devices.

17. The display device according to claim 16, wherein the light transmission region in each of the plurality of optical units is provided with a second light transmission layer, and each of the first light transmission layers is integrally formed with the second light transmission layer.

18. The display device according to claim 16, wherein a material of the first light shading layer and the second shading layer is a black matrix or metal;
a material of the first light transmission layer is polyimide or glass.

19. The display device according to claim 10, wherein the light shading region of each of the plurality of optical units is provided with a light shading body, and a through-hole defined by any adjacent two of the light shading bodies is the light transmission region.

20. The display substrate according to claim 7, wherein a material of the first light shading layer and the second light shading layer is a black matrix or metal;
a material of the first light transmission layer is polyimide or glass.
